(19) United States
(12) Patent Application Publication
(10) Pub. No.: US 2009/0208852 A1
(43) Pub. Date: Aug. 20, 2009

(54) PATTERN FORMING METHOD, SEMICONDUCTOR DEVICE MANUFACTURING METHOD AND SEMICONDUCTOR DEVICE MANUFACTURING APPARATUS

(75) Inventor: Satoru Shimura, Yamanashi (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/370,728

(22) Filed: Feb. 13, 2009

(30) Foreign Application Priority Data
Feb. 15, 2008 (JP) 2008-034463

(51) Int. Cl. G03F 1/00; G03F 7/00; G03B 27/42

(52) U.S. Cl. 430/5; 430/319; 355/53

(57) ABSTRACT

Provided are a pattern forming method capable of accurately forming a microscopic pattern without employing a hard mask, thereby simplifying a process in comparison to a conventional process and reducing a manufacturing cost of a semiconductor device, a semiconductor device manufacturing method and a semiconductor device manufacturing apparatus. A pattern forming method for forming a pattern having a predetermined shape and serving as a mask for etching, includes a process for forming a first pattern 106 by patterning a chemically amplified resist containing an acid generator, a process for forming a first pattern 107 having a solvent resistance and a developing solution resistance by bringing the first pattern 106 into contact with a basic solution or a basic gas, and a process for forming a second pattern 108 by patterning a chemically amplified resist containing an acid generator.

### FIELD OF THE INVENTION

The present disclosure relates to a pattern forming method for forming an etching mask used in performing an etching process such as a plasma etching process or the like on a substrate such as a semiconductor wafer or the like; and also relates to a semiconductor device manufacturing method and a semiconductor device manufacturing apparatus.

### BACKGROUND OF THE INVENTION

Conventionally, in a manufacturing process for a semiconductor device or the like, a microscopic circuit pattern has been formed by performing an etching process, e.g., a plasma etching process on a substrate such as a semiconductor wafer. In this etching process, a mask is formed by a photolithography process employing a photoresist.

With respect to this photolithography process, there have been developed various techniques so as to keep up with the miniaturization of a pattern to be formed. One example is so-called a double patterning. In the double patterning, a two-step patterning is performed. In one step, a first pattern made of a hard mask such as amorphous carbon is formed by a first lithography process of performing coating, exposure and development processes on a photoresist to form the first pattern, and an etching process; and in the other step, a second pattern is formed by a second lithography process of performing coating, exposure and development processes again on a photoresist after the first lithography process. By performing the two-step patterning, it is possible to form a mask having a finer gap in comparison to a mask formed by performing the patterning only once (for example, see Patent Document 1).

Patent Document 1: U.S. Pat. No. 7,064,078

### BRIEF SUMMARY OF THE INVENTION

As stated above, in the conventional double patterning technique, it was possible to perform the lithography process two times by using a hard mask. As a result, it is necessary to perform a film forming process of an amorphous carbon layer serving as the hard mask or an etching process on the amorphous carbon layer. Therefore, there have been problems that the process becomes complicated and the manufacturing cost of a semiconductor device increases.

In view of the foregoing, the present disclosure provides a pattern forming method capable of accurately forming a microscopic pattern without employing a hard mask, thereby simplifying the process in comparison to the conventional process and reducing the manufacturing cost of the semiconductor device; and also provides a semiconductor device manufacturing method and a semiconductor device manufacturing apparatus.

In accordance with one aspect of the present disclosure, there is provided a pattern forming method for forming a pattern having a predetermined shape and serving as a mask for etching an etching target layer on a substrate, the method including: a first pattern forming process for forming a first pattern by coating, exposing and developing a chemically amplified resist containing an acid generator; a solvent and developing solution resistance allowing process for allowing the first pattern to have a solvent resistance and a developing solution resistance by bringing the first pattern into contact with a basic solution or a basic gas; and a second pattern forming process for forming a second pattern by coating, exposing and developing a chemically amplified resist containing an acid generator.

The solvent and developing solution resistance allowing process includes a process for performing an ultraviolet irradiation.

The pattern forming method further includes a heating process between the solvent and developing solution resistance allowing process and the second pattern forming process.

The basic solution or the basic gas includes an amine-based material.

In accordance with another aspect of the present disclosure, there is provided a semiconductor device manufacturing method including a process for etching an etching target layer on a substrate by using a mask, wherein the mask is formed by a pattern forming method including: a first pattern forming process for forming a first pattern by coating, exposing and developing a chemically amplified resist containing an acid generator; a solvent and developing solution resistance allowing process for allowing the first pattern to have a solvent resistance and a developing solution resistance by bringing the first pattern into contact with a basic solution or a basic gas; and a second pattern forming process for forming a second pattern by coating, exposing and developing a chemically amplified resist containing an acid generator.

The solvent and developing solution resistance allowing process includes a process for performing an ultraviolet irradiation.

A heating process is included between the solvent and developing solution resistance allowing process and the second pattern forming process.

The basic solution or the basic gas includes an amine-based material.

In accordance with still another aspect of the present disclosure, there is provided a semiconductor device manufacturing apparatus for forming a mask for etching an etching target layer on a substrate, the apparatus including: a first pattern forming unit for forming a first pattern by coating, exposing and developing a chemically amplified resist containing an acid generator; a solvent and developing solution resistance allowing unit for allowing the first pattern to have a solvent resistance and a developing solution resistance by bringing the first pattern into contact with a basic solution or a basic gas; and a second pattern forming unit for forming a second pattern by coating, exposing and developing a chemically amplified resist containing an acid generator.

In accordance with the present disclosure, provided is a pattern forming method capable of accurately forming a microscopic pattern without employing a hard mask, thereby simplifying the process in comparison to the conventional process and reducing the manufacturing cost of the semiconductor device; and also provided are a semiconductor device manufacturing method and a semiconductor device manufacturing apparatus.

### BRIEF DESCRIPTION OF THE DRAWINGS

The disclosure may best be understood by reference to the following description taken in conjunction with the following figures:

FIGS. 1A to 1E are views for explaining a pattern forming method and a semiconductor device manufacturing method in accordance with an embodiment of the present disclosure;

FIG. 2 is a flowchart showing a process of the method of FIGS. 1A to 1E;

FIG. 3 is a flowchart showing a process of a modification; and

FIG. 4 is a block diagram showing a configuration of a semiconductor device manufacturing apparatus in accordance with an embodiment of the present disclosure.

### EXPLANATION OF CODES

101: Substrate
102: Base layer
103: Polysilicon layer
104: Hard mask layer
105: BARC
106: First pattern
107: Solvent and developing solution resistive first pattern
108: Second Pattern

### DETAILED DESCRIPTION OF THE INVENTION

Hereinafter, embodiments of the present disclosure will be described in detail with reference to the accompanying drawings.

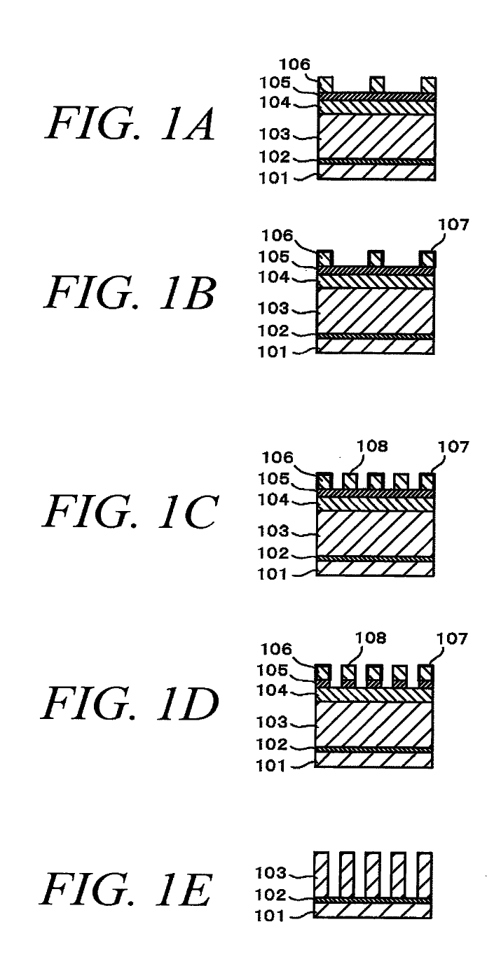

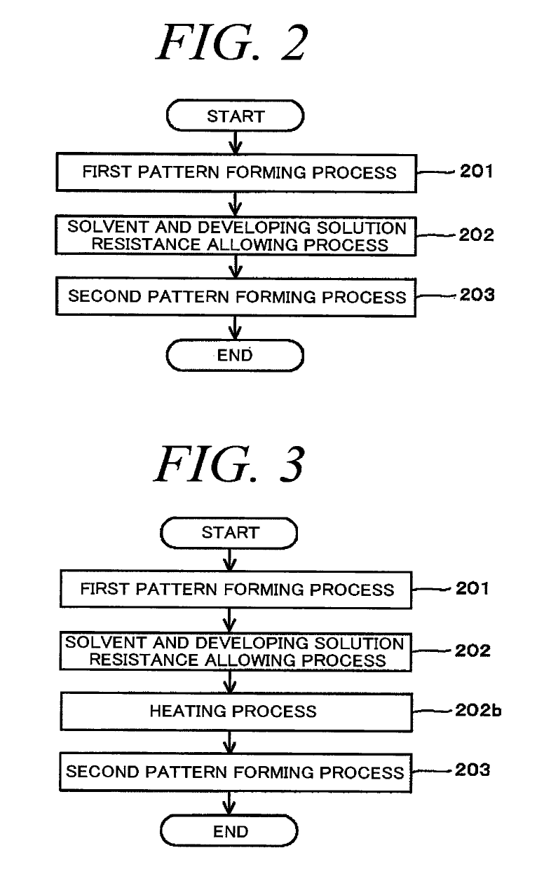

FIGS. 1A to 1E show enlarged schematic views of a part of a substrate in accordance with an embodiment of the present disclosure so as to illustrate a process of the present embodiment, and FIG. 2 is a flowchart showing the process of the present embodiment. As illustrated in FIGS. 1A to 1E, formed on a substrate 101 are a base layer 102, a polysilicon layer 103, a hard mask layer 104 and a BARC (anti-reflection layer) 105 in sequence from the bottom.

First, as illustrated in FIG. 1A, performed is a first pattern forming process (Step 201 of FIG. 2) for forming a first pattern 106, which is patterned into a predetermined pattern, by coating a chemically amplified resist containing an acid generator onto the BARC (anti-reflection layer) 105 and then performing exposure and development process thereon.

Subsequently, as illustrated in FIG. 1B, performed is a solvent and developing solution resistance allowing process (Step 202 of FIG. 2) in which a solvent and developing solution resistive first pattern 107 is obtained by bringing the first pattern 106 into contact with a basic solution or a basic gas to allow the first pattern 106 to have a solvent resistance and a developing solution resistance. In this solvent and developing solution resistance allowing process, it may be possible to use a solution or a gas of, for example, an amine based material (e.g., NH₃, (C₂H₅)₃N, C₆H₁₂N₄, C₆H₁₁NHC₆H₁₁ or the like) as the basic solution or the basic gas. In this manner, by bringing the first pattern 106 into contact with the basic solution or the basic gas, it is possible to prevent an action of the acid generator in the chemically amplified resist, and even if a second pattern forming process to be explained later is performed, the first pattern 106 can be prevented from being melted by a solvent or a developing solution. Further, although it may be possible to form the solvent and developing solution resistive first pattern 107 to cover at least a surface portion of the first pattern 106, it is also possible to make the entire pattern into the solvent and developing solution resistive first pattern 107.

Further, in the solvent and developing solution resistance allowing process, it may be possible to perform the contact with the basic solution or the basic gas together with an ultraviolet irradiation. The ultraviolet irradiation is performed to generate an acid from the acid generator of the chemically amplified resist, and by neutralizing the generated acid with the basic solution or the basic gas, the solvent resistance and the developing solution resistance of the first pattern 106 can be enhanced. The ultraviolet irradiation can be performed simultaneously with, or before or after the contact with the basic solution or the basic gas.

Thereafter, as illustrated in FIG. 1C, performed is a second pattern forming process (Step 203 of FIG. 2) for forming a second pattern 108, which is patterned into a predetermined pattern, between the first patterns 106 (the solvent and developing solution resistive first patterns 107) by coating again a chemically amplified resist containing an acid generator onto the surface thereof and then performing exposure and developing process thereon.

Through the above-stated processes, a pattern serving as an etching mask is formed. Then, by using this pattern as a mask, as illustrated in FIG. 1D, the BARC (anti-reflection layer) 105 is etched first, and then, the polysilicon layer 103 is etched by using the hard mask layer 104 onto which the pattern is transcribed as a mask.

As stated above, in the pattern forming process of the present embodiment, by performing the solvent and developing solution resistance allowing process in which the first pattern 106 is allowed to have the solvent resistance and the developing solution resistance, it is possible to prevent the first pattern 106 from being melted by a solvent or a developing solution while performing the second pattern forming process, and it is also possible to form a pattern by a double patterning process without using the hard mask. Accordingly, unlike the conventional process, there is no need for performing a film forming process or an etching process of the hard mask, and thus it is possible to simplify the process and reduce manufacturing cost of a semiconductor device.

The effect of allowing the solvent resistance and the developing solution resistance has been found by actually performing the solvent and developing solution resistance allowing process by using ammonia vapor. That is, the first pattern (pattern having a line width of 70 nm and a ratio of line to space equal to 1:1), which had gone through the solvent and developing solution resistance allowing process using the ammonia (NH₃) vapor, could remain unmelted and keep its shape even if it was immersed in a solvent (PGMEA (Polyethylene Glycol Monomethyl Ether Acetate)) for 60 seconds or in a developing solution (TMAH (TetraMethyl Ammonium Hydroxide)) for 60 seconds. Meanwhile, in case that the solvent and developing solution resistance allowing process was not performed, the pattern was melted when immersed in the solvent (PGMEA) for 60 seconds or in the developing solution (TMAH) for 60 seconds.

In addition, the effect of allowing the solvent resistance and the developing solution resistance has been found by using a triethylamine ((C₂H₅)₃N) vapor with respect to two kinds of chemically amplified resists (resist A and resist B). That is, with respect to the resist A, the first pattern (pattern having a line width of 70 nm and a ratio of line to space equal to 1:1), which had gone through the solvent and developing solution resistance allowing process using the triethylamine ((C₂H₅)₃N) vapor, could remain unmelted and keep its shape even if it was immersed in a solvent (PGMEA) for 60 seconds or in a developing solution (TMAH) for 60 seconds. Meanwhile, in case that the solvent and developing solution resistance allowing process was not performed, the pattern was melted when immersed in the solvent (PGMEA) for 60 seconds or in the developing solution (TMAH) for 60 seconds.

Further, with respect to the resist B, the first pattern (pattern having a line width of 55 nm and a ratio of line to space equal to 1:2), which had gone through the solvent and developing solution resistance allowing process using the triethylamine ((C₂H₅)₃N) vapor, could remain unmelted and keep its shape even if it was immersed in a solvent (PGMEA) for 60 seconds or in a developing solution (TMAH) for 60 seconds when the triethylamine vapor was employed together with an ultraviolet irradiation. Meanwhile, in case that the solvent and developing solution resistance allowing process was not performed or in case that only the ultraviolet irradiation was performed, the pattern was melted when immersed in the solvent (PGMEA) for 60 seconds or in the developing solution (TMAH) for 60 seconds.

As stated above, the effect of the solvent and developing solution resistance allowing process can be examined. Here, in case that the solvent and developing solution resistance allowing process is performed, if the basic components are oversupplied, such basic components may exert a negative effect on the chemically amplified resist containing the acid generator, which is coated in the second pattern forming process. For this reason, as illustrated in FIG. 3, the oversupplied basic components are removed by performing a heating process 202b between the solvent and developing solution resistance allowing process 202 and the second pattern forming process 203, so that it is possible to prevent the oversupplied basic components from exerting a negative effect on the chemically amplified resist containing the acid generator in the second pattern forming process.

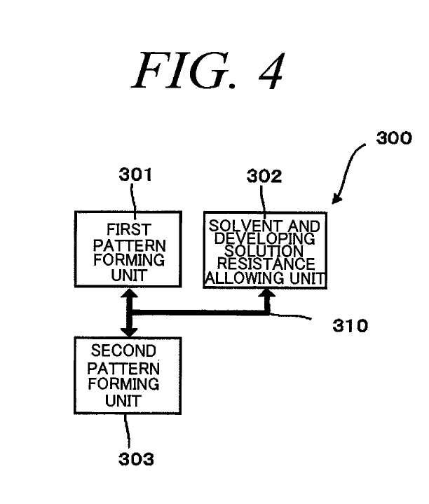

FIG. 4 shows a configuration of a semiconductor device manufacturing apparatus for performing the above-stated pattern forming method. As illustrated in the drawing, a semiconductor device manufacturing apparatus 300 includes a first pattern forming unit 301, a solvent and developing solution resistance allowing unit 302 and a second pattern forming unit 303. Further, each of these units is connected to each other by a substrate transfer path 310 for transferring a substrate such as a semiconductor wafer or the like.

The first pattern forming unit 301 is used for forming the first pattern 106, and includes a coating device, an exposure device, a developing device and the like. The solvent and developing solution resistance allowing unit 302 is used for performing the solvent and developing solution resistance allowing process, and includes a device for immersing the substrate in a basic solution or exposing the substrate to a basic gas, and may include an ultraviolet irradiation device and the like, if necessary. The second pattern forming unit 303 is used for forming the second pattern 108, and includes a coating device, an exposure device, a developing device and the like. With the semiconductor device manufacturing apparatus 300 configured as stated above, it is possible to perform a series of processes in the aforementioned embodiment. Further, the first pattern forming unit 301 and the second pattern forming unit 303 may be combined into a single pattern forming unit. Further, a heating unit for performing the heating process may be provided if necessary.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

What is claimed is:

1. A pattern forming method for forming a pattern having a predetermined shape and serving as a mask for etching an etching target layer on a substrate, the method comprising:
a first pattern forming process for forming a first pattern by coating, exposing and developing a chemically amplified resist containing an acid generator;
a solvent and developing solution resistance allowing process for allowing the first pattern to have a solvent resistance and a developing solution resistance by bringing the first pattern into contact with a basic solution or a basic gas; and
a second pattern forming process for forming a second pattern by coating, exposing and developing a chemically amplified resist containing an acid generator.

2. The pattern forming method of claim 1, wherein the solvent and developing solution resistance allowing process includes a process for performing an ultraviolet irradiation.

3. The pattern forming method of claim 1, further comprising:
a heating process between the solvent and developing solution resistance allowing process and the second pattern forming process.

4. The pattern forming method of claim 1, wherein the basic solution or the basic gas includes an amine-based material.

5. A semiconductor device manufacturing method comprising a process for etching an etching target layer on a substrate by using a mask, wherein the mask is formed by a pattern forming method including:
a first pattern forming process for forming a first pattern by coating, exposing and developing a chemically amplified resist containing an acid generator;
a solvent and developing solution resistance allowing process for allowing the first pattern to have a solvent resistance and a developing solution resistance by bringing the first pattern into contact with a basic solution or a basic gas; and
a second pattern forming process for forming a second pattern by coating, exposing and developing a chemically amplified resist containing an acid generator.

6. The semiconductor device manufacturing method of claim 5, wherein the solvent and developing solution resistance allowing process includes a process for performing an ultraviolet irradiation.

7. The semiconductor device manufacturing method of claim 5, wherein a heating process is included between the solvent and developing solution resistance allowing process and the second pattern forming process.

8. The semiconductor device manufacturing method of claim 5, wherein the basic solution or the basic gas includes an amine-based material.

9. A semiconductor device manufacturing apparatus for forming a mask for etching an etching target layer on a substrate, the apparatus comprising:
a first pattern forming unit for forming a first pattern by coating, exposing and developing a chemically amplified resist containing an acid generator;
a solvent and developing solution resistance allowing unit for allowing the first pattern to have a solvent resistance and a developing solution resistance by bringing the first pattern into contact with a basic solution or a basic gas; and
a second pattern forming unit for forming a second pattern by coating, exposing and developing a chemically amplified resist containing an acid generator.
